(19) United States
(12) Patent Application Publication
(10) Pub. No.: US 2012/0085283 A1
(43) Pub. Date: Apr. 12, 2012

(54) CORRECTION PLATE AND COATING DEVICE USING SAME

(75) Inventors: MING-YANG LIAO, Tu-Cheng (TW); CHIA-YING WU, Tu-Cheng (TW)

(73) Assignee: HON HAI PRECISION INDUSTRY CO., LTD., Tu-Cheng (TW)

(21) Appl. No.: 12/981,555

(22) Filed: Dec. 30, 2010

(30) Foreign Application Priority Data
Oct. 11, 2010 (TW) 99134536

(51) Int. Cl. C23C 16/52; C23C 16/00; C23C 16/44

(52) U.S. Cl. 118/715; 118/504

(57) ABSTRACT

A correction plate includes a supporting plate, a first moving blade array, a second moving blade array, a number of driving devices, and a control module. The first moving blade array and the second moving blade array are located at two opposite sides of the supporting plate. Each of the first moving blade array and the second moving blade array includes a number of blades aligned with each other. The driving devices are positioned on the supporting plate and connected to the blades correspondingly. The control module controls the driving devices to drive the blades to protrude from the two opposite sides of the supporting plate.

### BACKGROUND

1. Technical Field

The present disclosure relates to coating technologies and, particularly, to a correction plate using in a coating device capable of changing shape automatically.

2. Description of Related Art

Coating devices include an umbrella shaped stand, a coating materials source, and a correction plate. The umbrella shaped stand is used for supporting a number of work-pieces. The correction plate is positioned between the umbrella shaped stand and the coating materials source, and configured for correcting the thickness of films coated on the work-pieces. However, correction plates with different shapes are used in different coating conditions. It is inconvenient to change or change the shape of the correction plate before coating.

Therefore, it is desirable to provide a correction plate which can overcome the limitations described.

### BRIEF DESCRIPTION OF THE DRAWINGS

FIG. 1 is a cross-section of a coating device in accordance with an exemplary embodiment.

FIG. 2 is a schematic and isometric view of a correction plate of the coating device of FIG. 1.

FIG. 3 is similar to FIG. 2, but showing the correction plate in a working state.

### DETAILED DESCRIPTION

Embodiments of the disclosure will now be described in detail, with reference to the accompanying drawings.

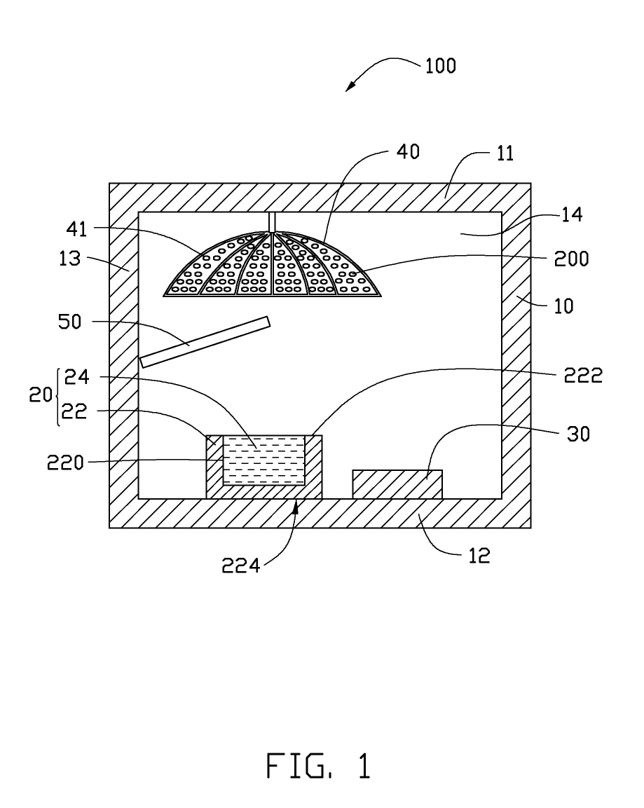

Referring to FIG. 1, a coating device 100, according to an exemplary embodiment, is configured for coating a number of work-pieces 200. The coating device 100 includes a shell 10, a coating material source 20, an evaporation source 30, an umbrella shaped stand 40, and a correction plate 50.

The shell 10 is a hollow cylinder configuration, and includes an upper plate 11, a lower plate 12, and a sidewall 13 interconnected between the upper plate 11 and the lower plate 12. The upper plate 11, the lower plate 12, and the sidewall 13 cooperatively define a chamber 14.

The coating material source 20 is received in the chamber 14 and is positioned on the lower plate 12. The coating material source 20 includes a crucible 22 and materials 24 received in the crucible 22. The crucible 22 includes an upper surface 222 and a lower surface 224 opposite to the upper surface 222. The crucible 22 defines a recess 220 in the upper surface 222, generally at center thereof. The materials 24 are received in the recess 220.

The evaporation source 30 is received in the chamber 14 and is positioned on the lower plate 12 and adjacent to the coating material source 20. The evaporation source 30 is configured for heating the materials 24 and changing the materials 24 from a solid state to a gaseous state. In this embodiment, the evaporation source 30 is an electron beam gun. An electron beam output from the electron beam gun is deflected by a magnetic field, and the electron beam hits and heats the materials 24.

The umbrella shaped stand 40 is received in the chamber 14 and is suspended from the upper plate 11. The umbrella shaped stand 40 is a hollow spherical cap and defines a number of supporting holes 41 thereon. Each of the work-pieces 200 is received in the corresponding supporting hole 41. The distance between the work-pieces 200 positioned at the edge of the umbrella shaped stand 40 and the coating material source 20 is different from the distance between the work-pieces 200 positioned at the center of the umbrella shaped stand 40 and the coating material source 20.

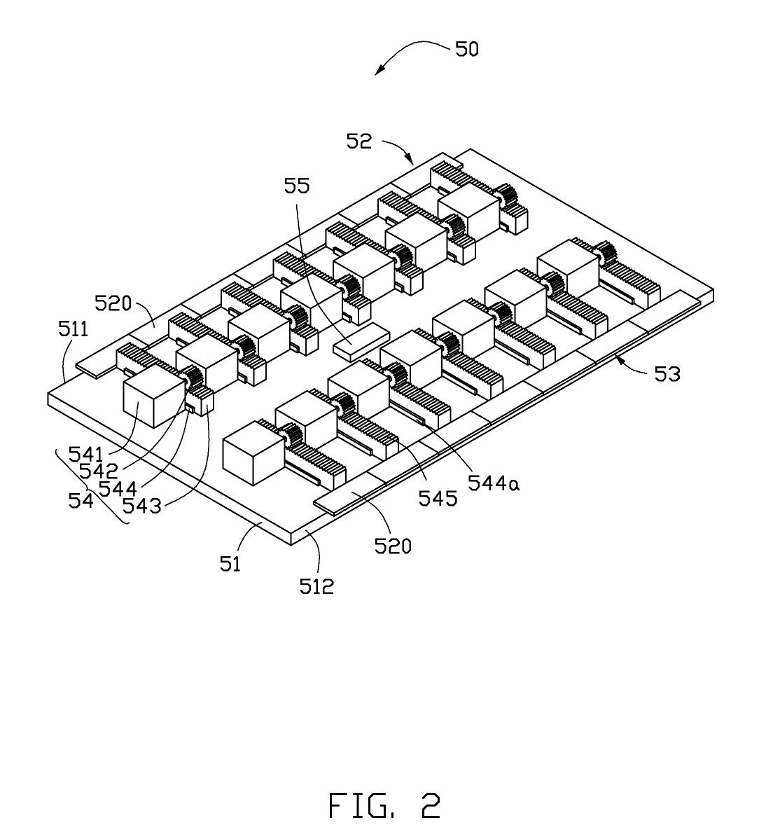

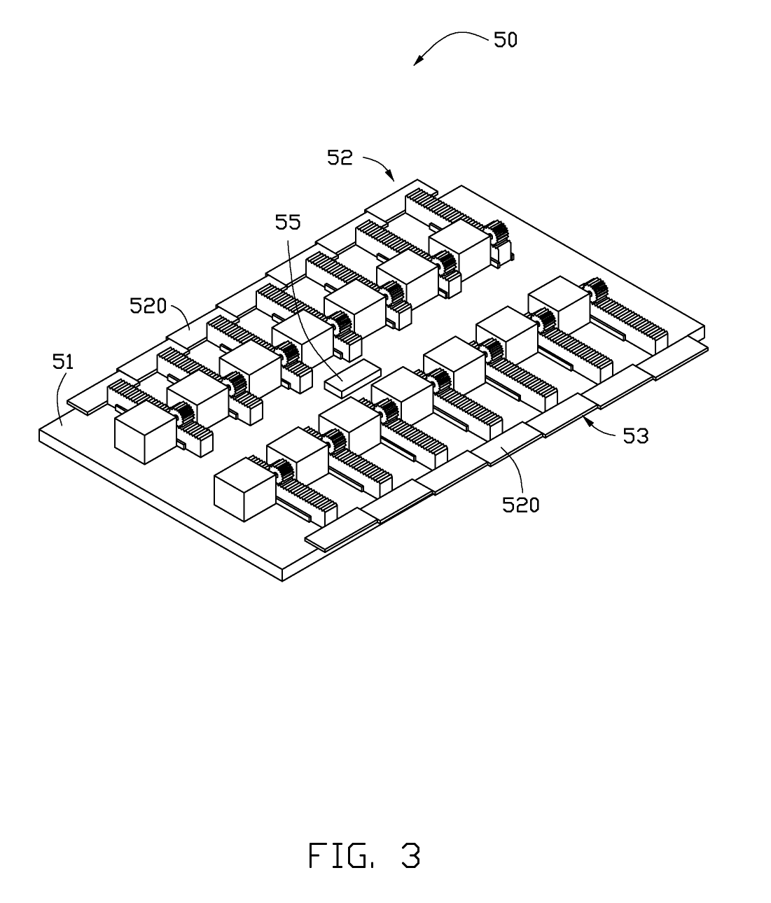

Also referring to FIGS. 2-3, the correction plate 50 is received in the chamber 14 and is positioned on the sidewall 13. The correction plate 50 is located between the evaporation source 30 and the umbrella shaped stand 40. The correction plate 50 includes a supporting plate 51, a first moving blade array 52, a second moving blade array 53, a number of driving devices 54, and a control module 55.

The supporting plate 51 is substantially rectangular and includes a first side 511 and a second side 512 opposite to the first side 511. The first moving blade array 52 and the second moving blade array 53 are respectively located at the first side 511 and the second side 512. Each of the first moving blade array 52 and the second moving blade array 53 includes a number of blades 520 aligned with each other. The blades 520 are arranged in two lines. One line of blades 520 are positioned at the first side 511, the other line of blades 520 are positioned at the second side 512. Each of the blades 520 is a substantially rectangular plate.

The number of the driving devices 54 is equal to the number of the blades 520. In this embodiment, the correction plate 50 includes fourteen driving devices 54. Each of the driving devices 54 includes a motor 541, a driving gear 542, a strip gear 543, and a guiding element 544. The driving gear 542 is a spur gear and sleeved on a shaft of the motor 541, and the motor 541 operates the driving gear 542. The rotation axis of the driving gear 542 is substantially parallel to the first side 511 and the second side 512. The strip gear 543 is movably positioned on the supporting plate 51, and the movement direction of the strip gear 543 is substantially perpendicular to the first side 511 and the second side 512. The strip gear 543 includes a toothed portion 545 facing away from the supporting plate 51. One end of each strip gear 543 is adjacent to the first side 511 or the second side 512 and connects to a corresponding one of the blades 520. The driving gear 543 is meshed with the toothed portion 545 of the strip gear 543. The guiding element 544 includes two strip plates 544a positioned substantially parallel on the supporting plate 51. The extending direction of the strip plates 544a is perpendicular to the first side 511 and the second side 512. The strip gear 543 is movably received between the two strip plates 544a of the guiding element 544.

The control module 55 is positioned on the supporting plate 51, and electrically connected with the motors 541 of the driving devices 54. The control module 55 receives a control signal, decodes the control signal into a driving signal and outputs the driving signal to the motors 541. In this embodiment, the control module 55 stores a number of driving signals corresponding to the different coating conditions.

In operation, a control signal is input to the control module 55, the control module 55 decodes the control signal and outputs a driving signal to each of the motors 541. The motors 541 rotate the driving gears 542, and the driving gears 542 drive the strip gears 543 to move along the guiding element 544. Each of the blades 520 protrudes from a different area of the first side 511 and the second side 512 of the supporting plate 51. Therefore, the shape of the correction plate 50 is changed. The thickness of the films coated on the work-piece 200 can be corrected.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A correction plate, comprising:
a supporting plate;
a first moving blade array and a second moving blade array respectively located at two opposite sides of the supporting plate, each of the first moving blade array and the second moving blade array comprising a plurality of blades aligned with each other;
a plurality of driving devices positioned on the supporting plate and connected to the blades correspondingly; and
a control module configured to control the driving devices to drive the blades to protrude from the two opposite sides of the supporting plate.

2. The correction plate of claim 1, wherein the supporting plate is rectangular shaped, and comprises a first side and a second side opposite to the first side, the first moving blade array and the second moving blade array are respectively located at the first side and the second side.

3. The correction plate of claim 2, wherein each of the driving devices comprises a motor, a driving gear, and a strip gear; the driving gear is a spur gear and sleeved on the motor, the rotation axis of the driving gear is substantially parallel to the first and second sides, the strip gear comprises a toothed portion facing away from the supporting plate, one end of the strip gear is adjacent to the first side or the second side and connects to a corresponding blade, the driving gear is meshed with the toothed portion of the strip gear.

4. The correction plate of claim 3, wherein each driving device further comprises a guiding element, the guiding element comprises two strip plates positioned substantially parallel on the supporting plate, each strip gear is movably received between the two strip plates of a corresponding guiding element.

5. The correction plate of claim 1, wherein each of the blades is a substantially rectangular plate.

6. A coating device, comprising:
a shell comprising an upper plate, a lower plate, and a sidewall connected between the upper plate and the lower plate;
a coating material source positioned on the lower plate and configured to receive a coating material;
an evaporation source positioned on the lower plate and adjacent to the coating material source, the evaporation source configured to heat the coating material;
an umbrella shaped stand positioned on the upper plate; and
a correction plate positioned on the sidewall and located between the evaporation source and the umbrella shaped stand, the correction plate comprising:
a supporting plate;
a first moving blade array and a second moving blade array respectively located at two opposite sides of the supporting plate; each of the first moving blade array and the second moving blade array comprising a plurality of blades aligned with each other; and
a plurality of driving devices positioned on the supporting plate and connected to the blades corresponding; and a control module configured to control the driving devices to drive the blades to protrude from the two opposite sides of the supporting plate.

7. The coating device of claim 6, wherein the supporting plate is rectangular shaped, and comprises a first side and a second side opposite to the first side, the first moving blade array and the second moving blade array are respectively located at the first side and the second side.

8. The coating device of claim 7, wherein each of the driving devices comprises a motor, a driving gear, and a strip gear; the driving gear is a spur gear and sleeved on the motor, the rotation axis of the driving gear is substantially parallel to the first and second sides, the strip gear comprises a toothed portion facing away from the supporting plate, one end of the strip gear is adjacent to the first side or the second side and connects to a corresponding blade, the driving gear is meshed with the toothed portion of the strip gear.

9. The coating device of claim 8, wherein the driving device further comprises a guiding element, the guiding element comprises two strip plates positioned substantially parallel on the supporting plate, each strip gear is movably received between the two strip plates of a corresponding guiding element.

10. The coating device of claim 6, wherein each of the blades is a substantially rectangular plate.

11. The coating device of claim 6, wherein the coating material source comprises a crucible, the crucible comprises an upper surface and a lower surface opposite to the upper surface, the lower surface contacts the lower plate, the crucible defines a recess for receiving the coating material.

12. The coating device of claim 6, wherein the evaporation source comprises an electron beam gun.
